(19) United States
(12) Patent Application Publication
(10) Pub. No.: US 2020/0099878 A1
(43) Pub. Date: Mar. 26, 2020

(54) CMOS IMAGE SENSOR WITH MULTIPLE STAGE TRANSFER GATE

(71) Applicant: OmniVision Technologies, Inc., Santa Clara, CA (US)

(72) Inventors: Gang Chen, San Jose, CA (US); Duli Mao, Sunnyvale, CA (US); Dyson Tai, San Jose, CA (US); Lindsay Grant, Campbell, CA (US)

(73) Assignee: OmniVision Technologies, Inc., Santa Clara, CA (US)

(21) Appl. No.: 16/141,584

(22) Filed: Sep. 25, 2018

(51) Int. Cl. H04N 5/376; H01L 27/146; H04N 5/378

(52) U.S. Cl. CPC H04N 5/376; H04N 5/378; H01L 27/14614

(57) ABSTRACT

An image sensor pixel comprises a first charge storage node configured to have a first charge storage electric potential; a second charge storage node configured to have a second charge storage electric potential and receive charge from the first charge storage node, wherein the second charge storage electric potential is greater than the first charge storage electric potential; and a transfer circuit coupled between the first and the second charge storage nodes, wherein the transfer circuit comprises at least three transfer regions, wherein: a first transfer region is proximate to the first charge storage node and configured to have a first transfer electric potential greater than the first charge storage electric potential and lower than the second charge storage electric potential; a second transfer region is coupled between the first and a third transfer region and configured to have a second transfer electric potential greater than the first charge storage electric potential and lower than the second charge storage electric potential; and the third transfer region is proximate to the third charge storage node and configured to have a third transfer electric potential greater than the first charge storage electric potential and lower than the second charge storage electric potential. Charges are fully transferred from the first charge storage node to the second charge storage node after a plurality of transfer signal pulses.

### TECHNICAL FIELD

This disclosure relates generally to semiconductor image sensors, and in particular but not exclusively, relates to CMOS image sensors with multiple stage transfer gates.

### BACKGROUND INFORMATION

Image sensors have become ubiquitous. They are widely used in digital still cameras, cellular phones, security cameras, as well as medical, automobile and other applications. The typical global shutter complementary metal oxide semiconductor (CMOS) image sensor is operated as follows: image charges accumulated in a photodiode from incident photons are transferred from the photodiode to a storage node, and then, subsequently to a floating diffusion node for global shutter read Out. The amount of generated image charges is proportional to the intensity of the image light. The generated image charges may be used to produce an image representing the external scene.

In order to accomplish the electric charge transfer from one node to another node, the nodes are frequently designed such that during operation, the node to which the charge is to be transferred (i.e., the destination node such as a floating diffusion node) has a greater electric potential than the node from which the electric charge is to be transferred (i.e., the source node such as photodiode node). In order to fully transfer electric charge from one node to another, the destination node may need to have an electric potential that is greater than the electric potential of the source node by an amount equal to or exceeding the amount of charge to be transferred. In other words, the destination node may need to have sufficient full well capacity to hold the electric charge from the source node without sharing the electric charge back with the source node when the barrier between the nodes is removed.

In order to achieve full electric charge transfer between a plurality of nodes, several solutions are used in the image sensor industry. The first solution is to increase the electric potential for successive nodes, with the increase in electric potential between each successive node generally equaling or exceeding the full well capacity for the pixel. However, this solution typically requires higher power supply voltages to be provided to the image sensor. The higher power supply voltage may result in higher power consumption, may require specialized processes to manufacture, and/or may require mitigation of electrostatic discharge issues. The second solution is to reduce the conversion gain between nodes. However, this solution may result in more noise and less sensitivity in operation of the image sensor. The third solution is to include additional nodes in image sensor pixels—for example, an image sensor formed by having two or more silicon chips stacked together. However, this solution may require additional contacts and storage nodes for charge to be transferred between the stacked silicon chips. The additional nodes exacerbate the need to increase the electric potential of subsequent storage nodes.

### BRIEF DESCRIPTION OF THE DRAWINGS

Non-limiting and non-exhaustive examples of the invention are described with reference to the following figures, wherein like reference numerals refer to like parts throughout the various views unless otherwise specified.

FIG. 1 is a block diagram schematically illustrating one example of an imaging system, in accordance with an embodiment of the disclosure.

FIG. 2 is a simplified schematic cross-section view of a portion of an image sensor pixel, in accordance with an embodiment of the disclosure.

FIG. 3A through FIG. 3I are simplified electric potential profiles of the image sensor pixel portion shown in FIG. 2. Illustrating its operation, in accordance with an embodiment of the disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

Examples of an apparatus and method for an image sensor with multiple stage transfer gates are described herein. In the following description, numerous specific details are set forth to provide a thorough understanding of the examples. However, one skilled in the relevant art will recognize that the techniques described herein can be practiced without one or more of the specific details, or with other methods, components, materials, etc. In other instances, well-known structures, materials, or operations are not shown or described in details in order to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meanings.

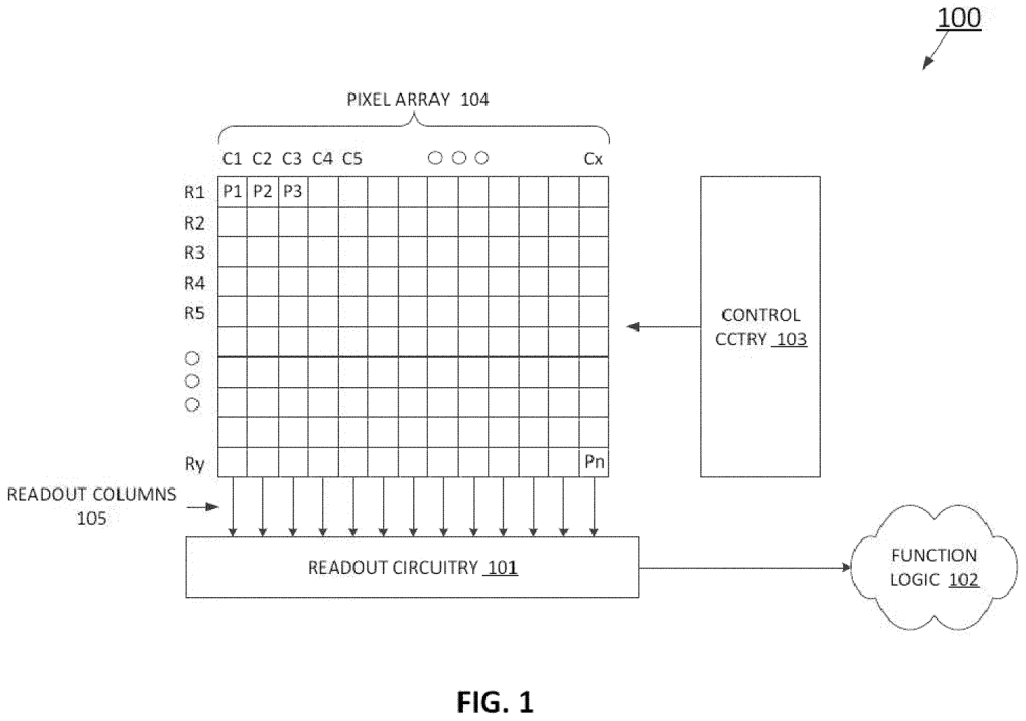

FIG. 1 is a block diagram illustrating one example of imaging system 100. Imaging system 100 includes pixel array 104, control circuitry 103, readout circuitry 101, and function logic 102. In one example, pixel array 104 is a two-dimensional (2D) array of photodiodes, or image sensor pixels (e.g., pixels P1, P2 . . . , Pn). As illustrated, photodiodes are arranged into rows (e.g., rows R1 to Ry) and columns (e.g., column C1 to Cx) to acquire image data of a person, place, object, etc., which can then be used to render a 2D image of the person, place, object, etc. However, in other examples, it is appreciated that the photodiodes do not have to be arranged into rows and columns and may take other configurations.

In one example, after the image sensor photodiode/pixel in pixel array 104 has acquired its image data or image charge, the image data is readout by readout circuitry 101 and then transferred to functional logic 102. In various examples, readout circuitry 101 may include amplification circuitry, analog-to-digital (ADC) conversion circuitry, or otherwise. Function logic 102 may simply store the image data or even manipulate the image data by applying post image effects (e.g., crop, rotate, remove red eye, adjust brightness, adjust contrast, or otherwise). In one example, readout circuitry 101 may read out a row of image data at a time along readout column lines (illustrated) or may readout the image data using a variety of other techniques (not illustrated), such as a serial readout or a full parallel readout of all pixels simultaneously.

In one example, control circuitry 103 is coupled to pixel array 104 to control operation of the plurality of photodiodes in pixel array 104. For example, control circuitry 103 may generate a shutter signal for controlling image acquisition. In one example, the shutter signal is a global shutter signal for simultaneously enabling all pixels within pixel array 104 to simultaneously capture their respective image data during a single acquisition window. In another example, the shutter signal is a rolling shutter signal such that each row, column, or group of pixels is sequentially enabled during consecutive acquisition windows. In another example, image acquisition is synchronized with lighting effects such as a flash.

In one example, imaging system 100 may be included in a digital camera, cell phone, laptop computer, automobile or the like. Additionally, imaging system 100 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 100, extract image data from imaging system 100, or manipulate image data supplied by imaging system 100.

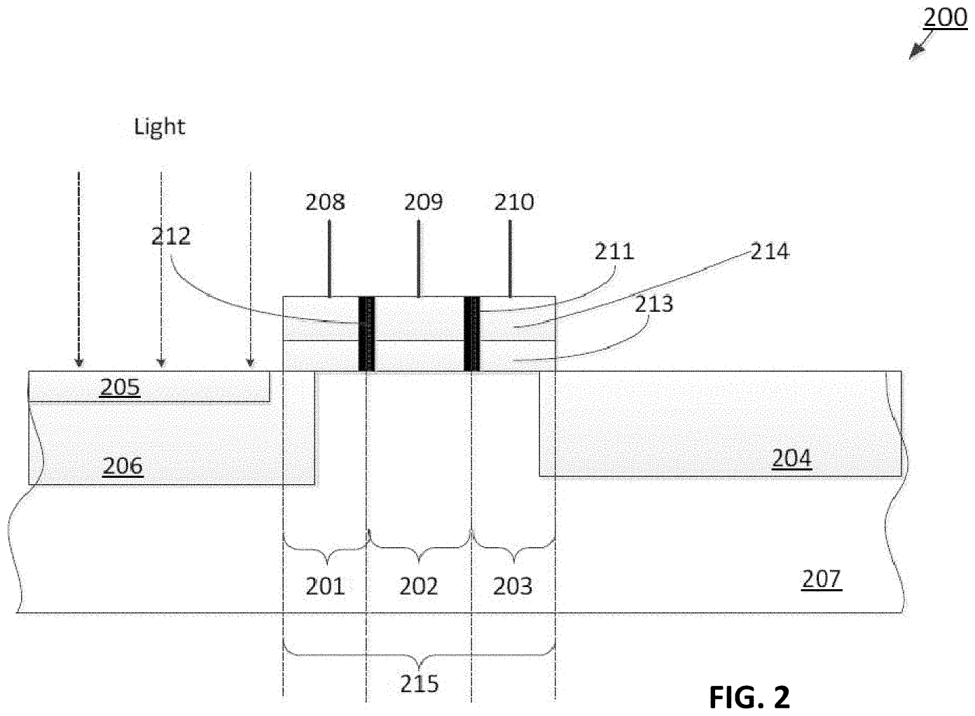

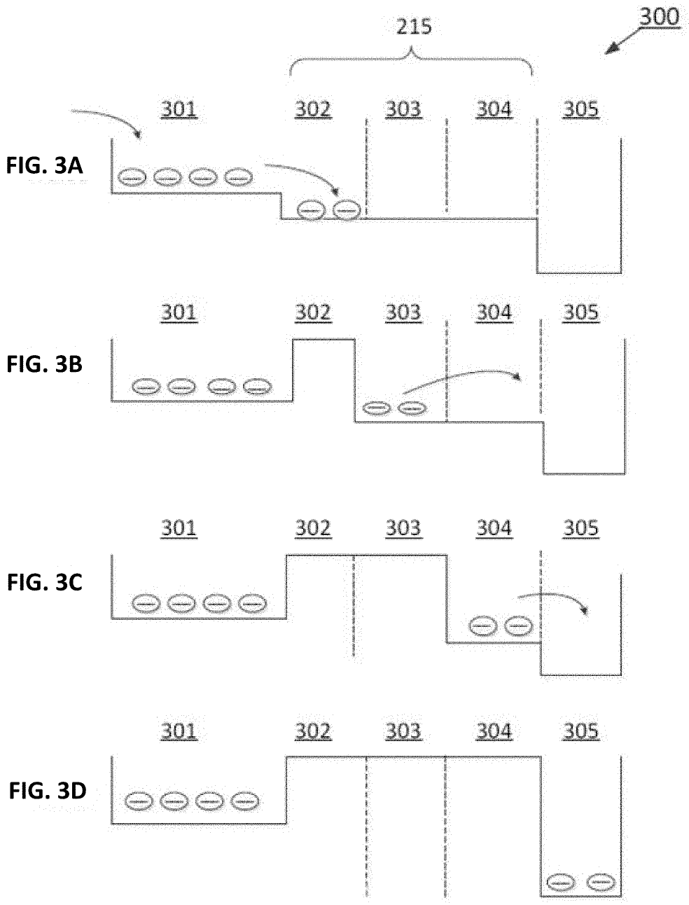

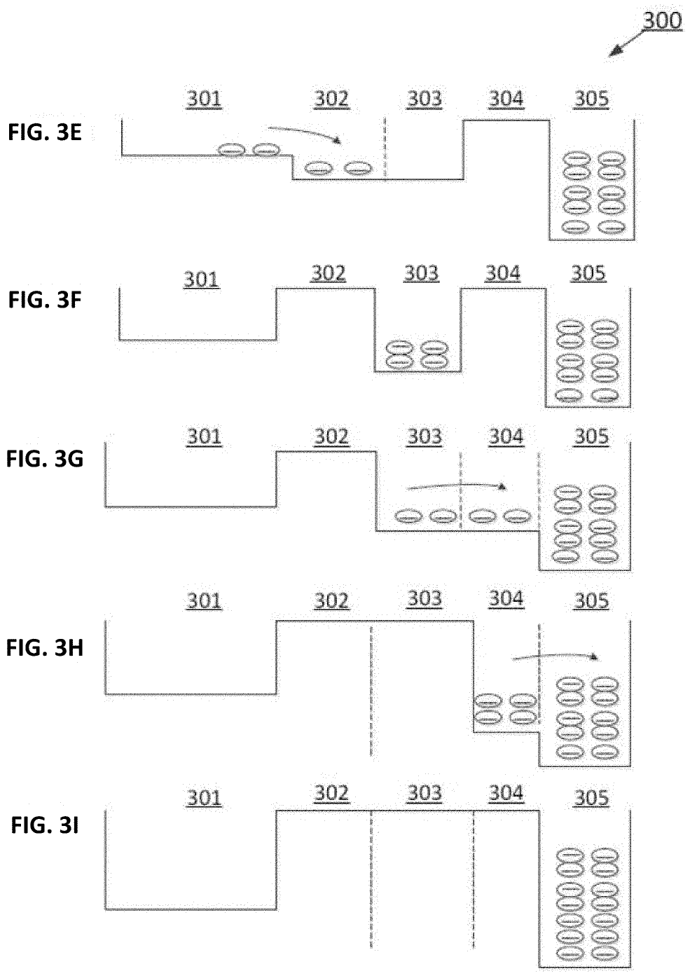

FIG. 2 is a simplified schematic cross-section view of a portion of an image sensor pixel 200, in accordance with an embodiment of the disclosure. The imaging sensor pixel 200 is one possible implementation of at least one pixel of pixel array 104 shown in FIG. 1. The illustrated embodiment of the imaging sensor pixel 200 includes a P-type doped semiconductor substrate 207 with a light receiving area. An N-type doped region 206 is disposed in the P-type doped semiconductor substrate 207 to form an electron-based photodiode in the light receiving area. In order to reduce the dark current, a P+ pinning layer 205 is also formed on the surface of the light receiving area. The N-typed region 206 and P+ pinning layer 205 form a first charge storage node 301 in FIG. 3A, which is configured to have a first charge storage electric potential. Another N-typed doped region 204 is disposed in the semiconductor substrate 207 in order to form a floating diffusion node as a second charge storage node 305 in FIG. 3A, which is configured to have a second charge storage electric potential and receive charge from the first charge storage node 301.

It should be noted that the term “photodiode” as used herein, is meant to encompass substantially any type of photon or light detecting component, such as a hole-based photodiode, a photo-gate or other photo-sensitive region. It should also be noted that different types of semiconductor substrates with different types of doping may also be used in different embodiments, and the two charge storage nodes 301 and 305 may be either n-doped regions in a p-type substrate or a p-well of a semiconductor substrate.

In FIG. 3A, a transfer circuit 215 is coupled between the first charge storage node 301 and the second charge storage node 305. The transfer circuit 215 comprises at least three transfer regions: a first transfer region 302 is proximate to the first charge storage node 301, which could be configured to have a first transfer electric potential greater than the first charge storage electric potential and lower than the second charge storage electric potential; a second transfer region 303 is coupled between the first 302 and a third 304 transfer region, which could be configured to have a second transfer electric potential greater than the first charge storage electric potential and lower than the second charge storage electric potential; and the third transfer region 304 is proximate to the second charge storage node 305, which could be configured to have a third transfer electric potential greater than the first charge storage electric potential and lower than the second charge storage electric potential. In FIG. 2, as an example, the transfer circuit 215 comprises a modified gate of a field effect transistor formed on a semiconductor substrate 207. The modified gate of the field effect transistor is positioned over a commonly doped region of the semiconductor substrate 207. The modified gate of the field effect transistor is partitioned into at least three regions, wherein a first region 201 is associated with the first transfer region 302 in FIG. 3A, a second region 202 is associated with the second transfer region 303 in FIG. 3A, and a third region 203 is associated with the third transfer region 304 in FIG. 3A. As an example, the first transfer region 201 comprises a first input electrode 208 configured to control the first transfer electric potential; the second transfer region 202 comprises a second input electrode 209 configured to control the second transfer electric potential; and the third transfer region 203 comprises a third input electrode 210 configured to control the third transfer electric potential. As an example, the transfer electric potential of each transfer region could be configured by varying the applied voltage at each of the input electrodes. Each of the input electrodes comprises at least one of poly silicon film, metal film and metal compounds. As an example, each of the input electrodes comprises a film stack of poly crystal silicon or metal gate 214 on the top of a thin gate dielectric 213 which is disposed directly on the semiconductor substrate 207. The first input electrode 208, the second input electrode 209 and the third input electrode 210 are electrically isolated from each other by isolation structures 211 and 212. As an example, the isolation structures may be formed by trenches filled with silicon oxide. The first transfer electric potential, the second transfer electric potential and the third transfer electric potential can be configured to be substantially the same. As another example, the first transfer electric potential can be configured to be lower than the second transfer electric potential and the second transfer electric potential is lower than the third transfer electric potential. Compared to the first, second and third transfer electric potentials, the first charge storage electric potential is always configured to be the lowest and the second charge storage electric potential is always configured to be the highest in the image sensor pixel 200.

FIG. 3A through FIG. 3I are simplified electric potential profiles of the image sensor pixel portion shown in FIG. 2 to illustrate its operation of a method of transferring charge from a first charge storage node 301 with a first charge storage electric potential to a second charge storage node 305 with a second charge storage electric potential in an image sensor pixel 200, in accordance with an embodiment of the disclosure. As an example, when the light is received in the light receiving area and converted to electrons, the first transfer electric potential of the first transfer region 302 proximate the first charge storage node 301 is increased such that the first transfer electric potential is greater than the first charge storage electric potential. As a result, electrons start to transfer from the first charge storage node 301 to the first transfer region 302 (FIG. 3A).

Meanwhile, the second transfer electric potential of the second transfer region 303 between the first transfer region 302 and the third transfer region 304 is also increased such that the second transfer electric potential is not lower than the first transfer electric potential. As one example, the second transfer electric potential is approximately the same as the first transfer electric potential. As another example, the second transfer electric potential is higher than the first transfer electric potential. Consequently, electrons continue to transfer from the first transfer region 302 to the second transfer region 303. After electrons “fall” into the second transfer region 303, the first transfer electric potential of the first transfer region 302 is decreased such that the decreased first transfer electric potential is less than the first charge storage electric potential of the first charge storage node 301 (FIG. 3B). Therefore, electrons in the second transfer region 303 will not flow back into the first charge storage node 301.

In order to continue transfer the electrons, the third transfer electric potential of the third transfer region 304 proximate the second charge storage node 305 is also increased at proximately the same time or after the first transfer electric potential is decreased such that the third transfer electric potential is also not lower than the second transfer electric potential and moreover not higher than the second charge storage electric potential. As a result, electrons continue to transfer from the second transfer region 303 to the third transfer region 304 (FIG. 3C) and finally “fall” into the second charge storage node 305 which has the highest electric potential (FIG. 3D). As one example, the third transfer electric potential is approximately the same as the second transfer electric potential. As another example, the third transfer electric potential is higher than the second transfer electric potential. As one example, the third transfer electric potential is lower than the second charge storage electric potential. As another example, the third transfer electric potential is approximately the same as the second charge storage electric potential.

After electrons “fall” into the third transfer region 304, the second transfer electric potential of the second transfer region 303 is decreased such that the decreased second transfer electric potential is approximately the same as or lower than the decreased first transfer electric potential of the first transfer region 302 (FIG. 3C), wherein both of them are lower than the first charge storage electric potential of the first charge storage node 301. Therefore, electrons in the third transfer region 304 will not flow back into the first charge storage node 301 but only flow into the second charge storage node 305 (FIG. 3D).

After electrons “fall” into the second charge storage node 305, the third transfer electric potential of the third transfer region 304 is decreased such that the decreased third transfer electric potential is less than the first charge storage electric potential of the first charge storage node 301 as well (FIG. 3D). Therefore, electrons in the second charge storage node 305 will not flow back into the first charge storage node 301. As one example, the decreased third transfer electric potential of the third transfer region 304 is approximately the same as the decreased first transfer electric potential of the first transfer region 302 and the decreased second transfer electric potential of the second transfer region 303, wherein all of them are less than the first charge storage electric potential of the first charge storage node 301 and the second charge storage electric potential of the second charge storage node 305, wherein the second charge storage electric potential of the second charge storage node 305 is the highest electric potential (FIG. 3D).

As an example, the transfer electric potential of each transfer region could be configured by varying the applied voltage as the charge transfer signal at each of the input electrodes for each of the transfer regions. During charge transfer, a plurality of pulses are provided to the input electrodes in order to transfer charges in sequence from the first charge storage node 301 to the second charge storage node 305 as described in previous paragraphs. The sequence of charge transfer does not necessarily have to be limited to the same sequence described in previous paragraphs. As one example, at the beginning of a new charge transfer cycle, the first transfer electric potential, the second transfer electric potential and the third transfer electric potential may be increased at substantially the same time (FIG. 3A), or increased one by one (FIG. 3E), in response to the charge transfer signals. The charge transfer operation described in previous paragraphs may be repeated with the plurality of transfer signal pulses until all the charges in the first charge storage node 301 are fully transferred into the second charge storage node 305 (FIG. 3A˜3I). Moreover, the transfer circuit 215 may comprise more than three transfer regions in order to achieve higher full well capacity.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize. These modifications can be made to the invention in light of the above detailed description. The terms used in the following claims should not be construed to limit the invention to the specific examples disclosed in the specification. Rather, the scope of the invention is to be determined entirely by the following claims, which are to be constructed in accordance with established doctrines of claim interpretation.

What is claimed is:

1. An image sensor pixel, comprising:
a first charge storage node configured to have a first charge storage electric potential;
a second charge storage node configured to have a second charge storage electric potential and receive charge from the first charge storage node, wherein the second charge storage electric potential is greater than the first charge storage electric potential; and
a transfer circuit coupled between the first and the second charge storage nodes, wherein the transfer circuit comprises at least three transfer regions, wherein:
a first transfer region is proximate to the first charge storage node and configured to have a first transfer electric potential greater than the first charge storage electric potential and lower than the second charge storage electric potential;
a second transfer region is coupled between the first and a third transfer region and configured to have a second transfer electric potential greater than the first charge storage electric potential and lower than the second charge storage electric potential; and
the third transfer region is proximate to the third charge storage node and configured to have a third transfer electric potential greater than the first charge storage electric potential and lower than the second charge storage electric potential.

2. The image sensor pixel of claim 1, wherein:
the first transfer region comprises a first input electrode configured to control the first transfer electric potential;
the second transfer region comprises a second input electrode configured to control the second transfer electric potential;
the third transfer region comprises a third input electrode configured to control the third transfer electric potential; and
the first input electrode, the second input electrode and the third input electrode are electrically isolated from each other.

3. The image sensor pixel of claim 1, wherein the first transfer electric potential, the second transfer electric potential and the third transfer electric potential are substantially the same.

4. The image sensor pixel of claim 1, wherein the first transfer electric potential is lower than the second transfer electric potential.

5. The image sensor pixel of claim 1, wherein the second transfer electric potential is lower than the third transfer electric potential;

6. The image sensor pixel of claim 1, wherein the first charge storage node comprises a photodiode disposed in a semiconductor substrate.

7. The image sensor pixel of claim 6, wherein the second charge storage node comprises a floating diffusion node disposed in the semiconductor substrate.

8. The image sensor pixel of claim 7, wherein the transfer circuit comprises a modified gate of a field effect transistor formed on the semiconductor substrate.

9. The image sensor pixel of claim 8, wherein the modified gate of the field effect transistor is partitioned into at least three adjacent regions isolated from each other, wherein a first region is associated with the first transfer region and comprises the first input electrode, a second region is associated with the second transfer region and comprises the second input electrode, and a third region is associated with the third transfer region and comprises the third input electrode.

10. The image sensor pixel of claim 8, wherein the modified gate of the field effect transistor is positioned over a commonly doped region of the semiconductor substrate.

11. The image sensor pixel of claim 1, wherein the first input electrode, the second input electrode and the third input electrode comprise at least one of poly crystal silicon, metal and metal compounds.

12. A method of transferring charge from a first charge storage node with a first charge storage electric potential to a second charge storage node with a second charge storage electric potential in an image sensor pixel, comprising:
increasing, responsive to a first transfer signal, a first transfer electric potential of a first transfer region proximate the first charge storage node such that an increased first transfer electric potential is greater than the first charge storage electric potential but lower than the second charge storage electric potential;
increasing, responsive to a second transfer signal, a second transfer electric potential of a second transfer region adjacent between the first transfer region and a third transfer region such that an increased second transfer electric potential is not lower than the increased first transfer electric potential but lower than the second charge storage electric potential;
decreasing, responsive to a third transfer signal, the first transfer electric potential of the first transfer region such that a decreased first transfer electric potential is less than the first charge storage electric potential;
increasing, responsive to a fourth transfer signal, a third transfer electric potential of the third transfer region proximate the second charge storage node such that an increased third transfer electric potential is not lower than the increased second transfer electric potential and not higher than the second charge storage electric potential, wherein the second charge storage electric potential is greater than the first charge storage electric potential;
decreasing, responsive to a fifth transfer signal, the second transfer electric potential of the second transfer region such that a decreased second transfer electric potential is substantially the same as the decreased first transfer electric potential; and
decreasing, responsive to a sixth transfer signal, the third transfer electric potential of the third transfer region such that a decreased third transfer electric potential is substantially the same as the decreased first transfer electric potential.

13. The method of claim 12, wherein the first, second, third, fourth, fifth, and sixth transfer signal are repeatedly provided as a plurality of pulses in order to fully transfer charges from the first charge storage node to the second charge storage node after said plurality of pulses.

14. The method of claim 12, wherein the increased first transfer electric potential is lower than the increased second transfer electric potential and the increased second transfer electric potential is lower than the increased third transfer electric potential.

15. The method of claim 12, wherein the first charge storage node comprises a photodiode.

16. The method of claim 12, wherein the second charge storage node comprises a floating diffusion node.

17. The method of claim 12, further comprising a transfer circuit, wherein the transfer circuit comprises a modified gate of a field effect transistor formed on a semiconductor substrate, wherein the modified gate of the field effect transistor is partitioned into at least three regions, wherein a first region is associated with the first transfer region, a second region is associated with the second transfer region and a third region is associated with the third transfer region.

18. The method of claim 17, wherein the modified gate of the field effect transistor is positioned over a commonly doped region of the semiconductor substrate.

19. The method of claim 12, wherein:
the first transfer region comprises a first input electrode configured to control the first transfer electric potential;
the second transfer region comprises a second input electrode configured to control the second transfer electric potential;
the third transfer region comprises a third input electrode configured to control the third transfer electric potential; and
the first input electrode, the second input electrode and the third input electrode are electrically isolated from each other.

20. The method of claim 19, wherein the first input electrode, the second input electrode and the third input electrode comprise at least one of poly crystal silicon, metal and metal compounds.
